(19) United States
(12) Patent Application Publication
(10) Pub. No.: US 2011/0305010 A1
(43) Pub. Date: Dec. 15, 2011

(54) POLE WITH SOLAR MODULES

(76) Inventors: Kevin Franklin Leadford, Evergreen, CO (US); Peter K. Nelson, Denver, CO (US)

(21) Appl. No.: 13/157,119

(22) Filed: Jun. 9, 2011

Related U.S. Application Data
(60) Provisional application No. 61/352,938, filed on Jun. 9, 2010.

(51) Int. Cl. F21L 4/08; H01M 10/46; H02J 4/00; H01L 31/052

(52) U.S. Cl. 362/183; 136/244; 136/246; 320/101; 307/18

(57) ABSTRACT

Poles having solar power capabilities and, more specifically, poles that include solar modules (hereinafter “solar poles”) are disclosed. In some embodiments, the solar modules are positioned within a solar pole. A solar module can include, for example, a solar cell and at least one planar reflective surface situated near the solar cell. The reflective surfaces reflect and focus light onto the solar cells, thereby increasing the amount of light and energy collected by individual solar cells.

### CROSS-REFERENCES TO RELATED APPLICATIONS

This is a non-provisional application that claims the benefit of commonly assigned U.S. Provisional Application No. 61/352,938, filed Jun. 9, 2010, entitled “Pole With Solar Modules,” the entirety of which is herein incorporated by reference for all purposes.

### BACKGROUND OF THE INVENTION

Most lighting fixtures are powered directly by the national power grid. Given the prevailing emphasis on energy conservation and green energy sources, outdoor lighting systems are a compelling platform for the application of renewable energy technologies, such as wind and solar power generation. Some outdoor lighting systems include structural frameworks that can be used for more than one purpose. For example, a structure can include signage, lighting, roadway marking, etc. And outdoor lighting systems can incorporate renewable energy technologies with little negative impact on land use and planning. Moreover, outdoor lighting equipment provides a highly visible yet fully practical way for property owners to demonstrate their commitment to so called “green” initiatives. This is in contrast to many green building practices (e.g., the use of advanced materials or higher efficiency components) that are relatively invisible to customers or the public. Such visibility is increasingly important as businesses seek to appeal to a more environmentally-concerned public.

Solar or wind powered outdoor lighting fixtures have been typically designed for autonomous or “off grid” operation. Such autonomous lighting fixtures generally employ batteries that are charged by the sun and/or the wind. At night or in the absence of wind, the lighting fixtures operate by drawing power from the batteries. The batteries may store enough energy to operate the lighting fixtures for several days without wind or sunshine. However, few existing autonomous systems are capable of providing light levels equal to that of conventional electric lighting systems at conventional pole spacing and extended periods of uncooperative weather are problematic. In addition, autonomous systems are relatively expensive and require periodic maintenance. Battery life typically ranges from about four to seven years, and replacements routinely cost as much as ten times the amount of energy saved over that period. Pole and installation costs are higher as well due to the presence of additional system components and their impact on wind loading. Both wind turbines and solar panels create wind resistance, which translates to an increased overturning moment, especially when the turbines or panels are located near the top of the pole, as is typical. The pole and its concrete base must also both be sized to resist this overturning moment, significantly increasing installation costs. Another drawback of conventional autonomous systems has to do with aesthetics. Many people consider large solar panels and wind turbines unsightly. Their orientation is usually chosen to maximize the amount of energy produced, and this orientation rarely complements the surrounding architecture or the landscape. However, autonomous systems can offer the advantage of independence from the national power grid, which can be important where electrical power is unavailable such as third world countries and national parks, or in times of natural or man-made disasters.

### BRIEF SUMMARY

Embodiments of the present invention relate to poles having solar power capabilities and, more specifically, poles that include solar modules (hereinafter “solar poles”). In some embodiments, the solar modules are positioned within a solar pole. A solar module can include, for example, a solar cell and at least one reflective surface situated near the solar cell. The reflective surface reflects and focuses light onto the solar cell, thereby increasing the amount of light and energy collected by individual solar cells.

The terms “invention,” “the invention,” “this invention” and “the present invention” used in this patent are intended to refer broadly to all of the subject matter of this patent and the patent claims below. Statements containing these terms should not be understood to limit the subject matter described herein or to limit the meaning or scope of the patent claims below. Embodiments of the invention covered by this patent are defined by the claims below, not this summary. This summary is a high-level overview of various aspects of the invention and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to the entire specification of this patent, all drawings and each claim.

### BRIEF DESCRIPTION OF THE DRAWINGS

Illustrative embodiments of the present invention are described in detail below with reference to the following drawing figures:

FIG. 1A is a perspective view of a solar pole according to some embodiments of the invention.

FIG. 1B is a perspective view of a portion of a solar pole with a luminaire head according to some embodiments of the invention.

FIG. 2 is a cross-sectional slice of a structural portion of a solar pole according to some embodiments of the invention.

FIG. 3 is a perspective view of a solar pole module without a solar cell according to some embodiments of the invention.

FIG. 4 is a partially-exploded, perspective view of a plurality of solar modules shown in FIG. 3 disposed within an aperture of a solar pole according to some embodiments of the invention.

FIG. 5 is a cut-away view of a solar pole with associated solar modules according to some embodiments of the invention.

FIG. 6 is a detail view of the solar pole and associated solar modules of FIG. 5.

FIG. 7 is solar cell that can be used in some embodiments of the solar modules.

FIG. 8 is a view of a solar section and bottom section of a solar pole coupled together to form a single longer solar pole according to some embodiments of the invention.

FIGS. 9A and 9B are perspective and side views of a solar module assembly housing according to some embodiments of the invention.

FIG. 9C is a solar module assembly with multiple solar modules placed within the assembly according to some embodiments of the invention.

FIG. 9D is a portion of a solar pole with a solar module assembly disposed within the solar pole according to some embodiments of the invention.

FIG. 10 is a portion of a solar pole with a protective lens according to some embodiments of the invention.

### DETAILED DESCRIPTION

The subject matter of embodiments of the present invention is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

Embodiments of the present invention are directed toward poles with solar power generation capabilities. In some embodiments, a solar pole can include solar cells that are positioned within a pole. Reflective and/or refractive optics can be used to focus solar light onto the various solar cells. A solar pole may be coupled with an electrical grid and can provide power to the electrical grid. A solar pole can include one or more batteries that store electrical power received from sunlight. In some embodiments, a solar pole can include lights or other electrical components that can be powered directly from solar cells, batteries, and/or the electric grid.

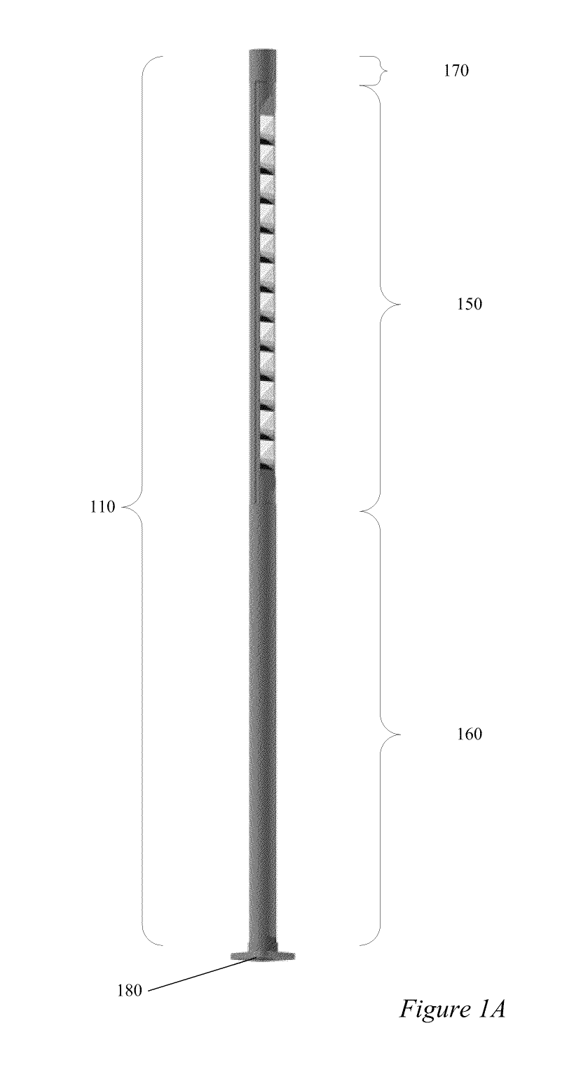

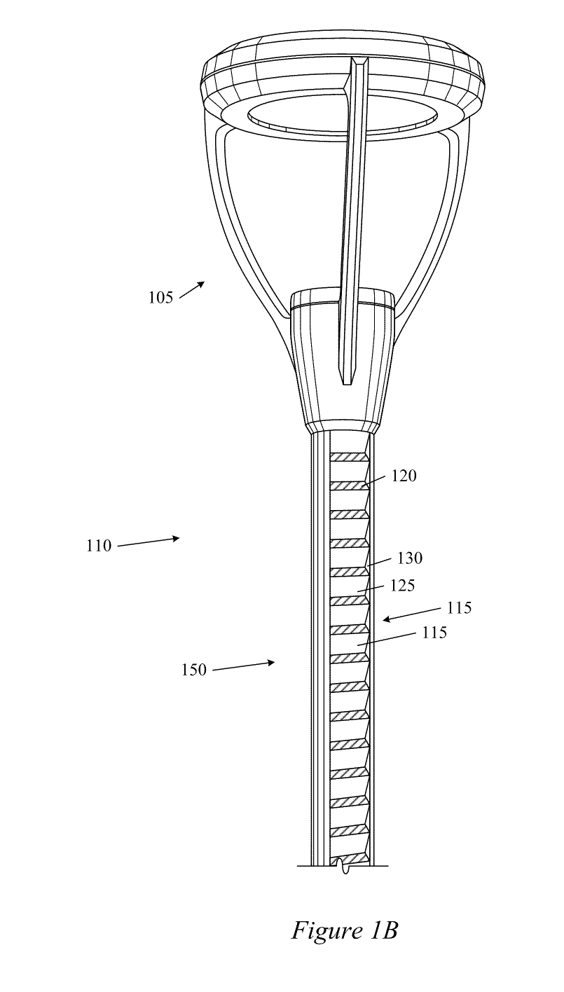

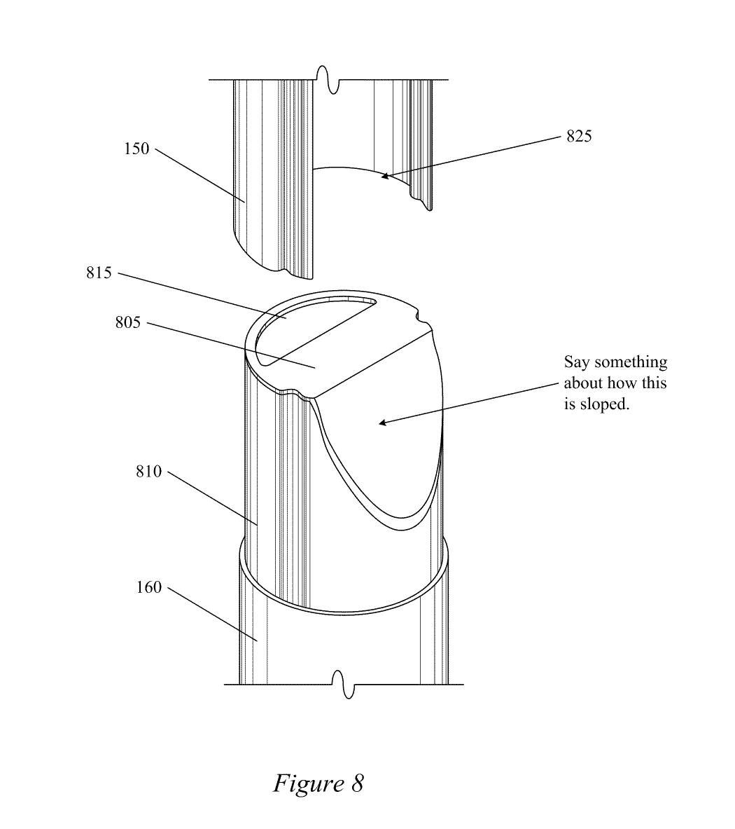

FIG. 1A shows solar pole 110 according to some embodiments of the invention. Solar pole 110 includes top section 170, solar section 150, and bottom section 160. Bottom section 160 is shown coupled with base 180. Top section 170 can be coupled with an electric fixture; for example, luminaire head 105 shown in FIG. 1B. Solar section 150 can include a channel with a plurality of solar cells, reflectors, solar modules, and/or solar assemblies disposed therein, as discussed in more detail below. The top section 170, solar section 150, and bottom section 160 may be integrally-formed as a single, monolithic pole. However, in some embodiments, each section is formed separately and then assembled to form a pole. Solar section 150 can be coupled with top section 170, bottom section 160, or another solar section, for example, in a mortise and tenon manner as shown in FIG. 8. However, other mechanical couplings would be readily understood by one of skill in the art and are certainly contemplated here. A solar system can include any combination of solar pole 110, base 180, and/or luminaire head 105.

Solar pole 110 can be constructed out of any material having suitable structural integrity to withstand typical outdoor conditions experienced by outdoor lighting fixtures, such as rain and wind shear. Non-limiting examples include steel, aluminum, fiberglass, concrete, and plastic. In some embodiments, solar pole 110 or any of its constituent parts can be extruded out of any of these materials.

FIG. 1B illustrates one embodiment of solar pole 110 with luminaire head 105 mounted on the solar pole 110. Luminaire head 105 can be coupled with top section 170. As shown in the figure, luminaire head 105 may slide over top section 170. Various other techniques can be used to couple top section 170 with luminaire head 105. Luminaire head 105 can house, among other things, a light source or sources.

Luminaire head 105, for example, can include light emitting diodes, fluorescent lamps, compact fluorescent lamps, HID lamps, metal halide lamps, high pressure sodium lamps, and mercury vapor lamps. A ballast or driver (depending on the light source) can be housed in luminaire head 105 or solar pole 110. While luminaire head 105 is described as a lighting device, any type of electric fixture can be used.

As discussed in much greater detail below, solar section 150 can include a plurality of solar cells 120 disposed along its length that can be used to collect solar energy and convert it to electricity. The ballast or driver can be electrically tied to the national electric power grid, which can supply electricity to power luminaire head 105. However, the ballast or driver may also be electrically tied to the solar cells disposed within the solar pole or an internal battery. Thus, the national electric power grid, the solar modules, a battery, or any combination thereof may power the light source(s) in luminaire head 105.

Embodiments of the invention are not limited to lighting fixture applications. Rather, luminaire head 105 may be any electrically powered accessory. Moreover, to the extent that solar pole 110 includes a luminaire head, embodiments of the invention are not intended to be limited for use with a specific luminaire head like luminaire head 105 depicted in FIG. 1. Rather, solar pole 110 can be used with any suitable luminaire head, lighting fixture, electrical accessory, and/or with any associated light source or sources.

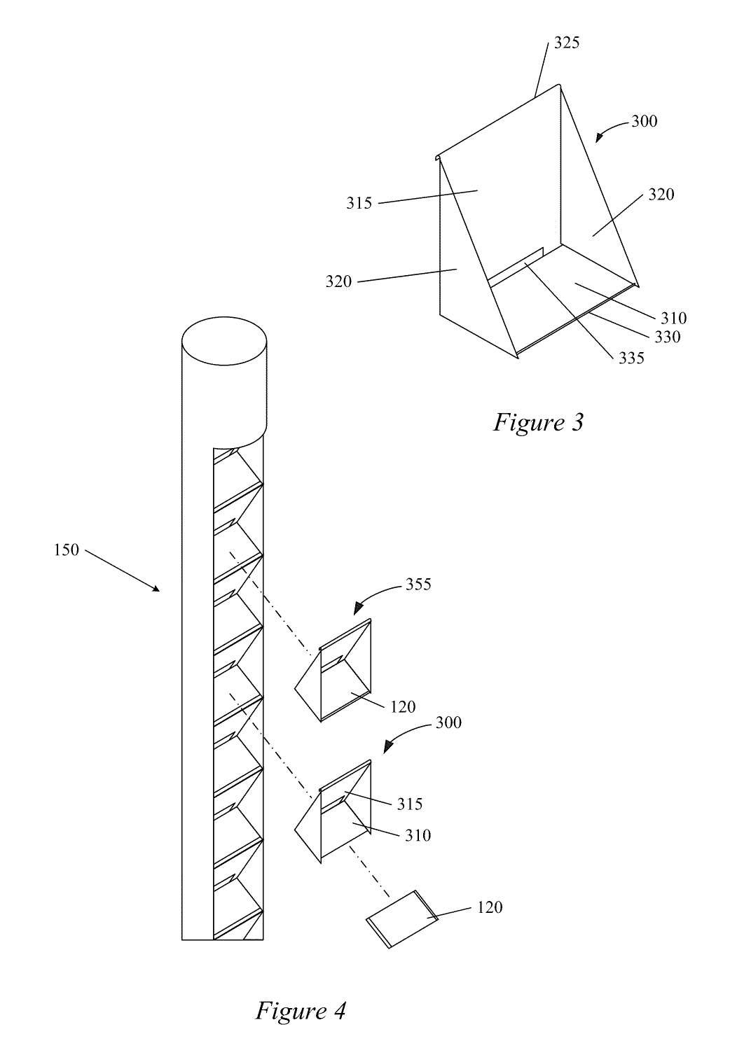

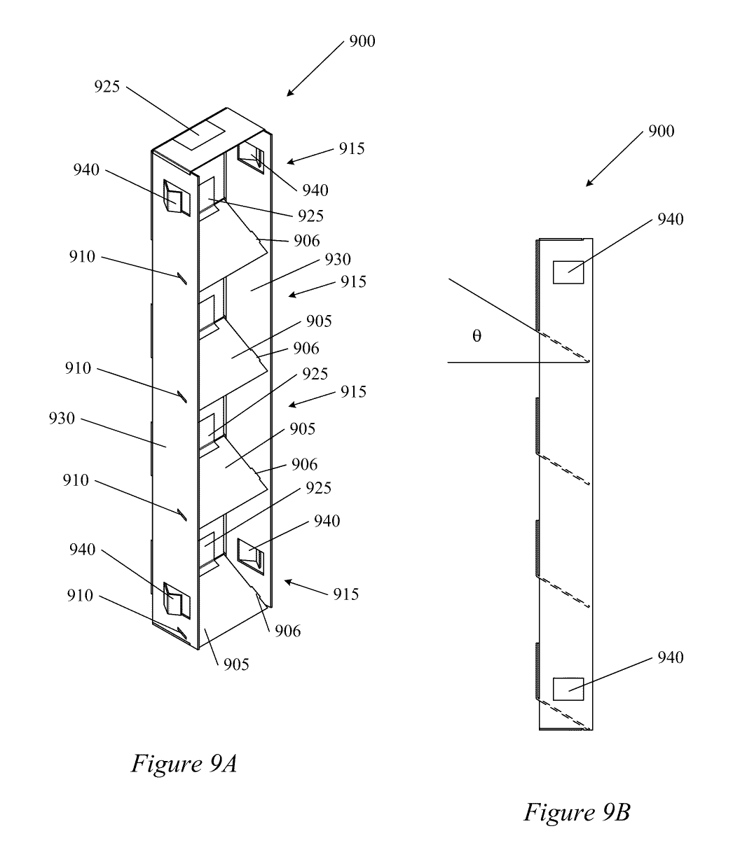

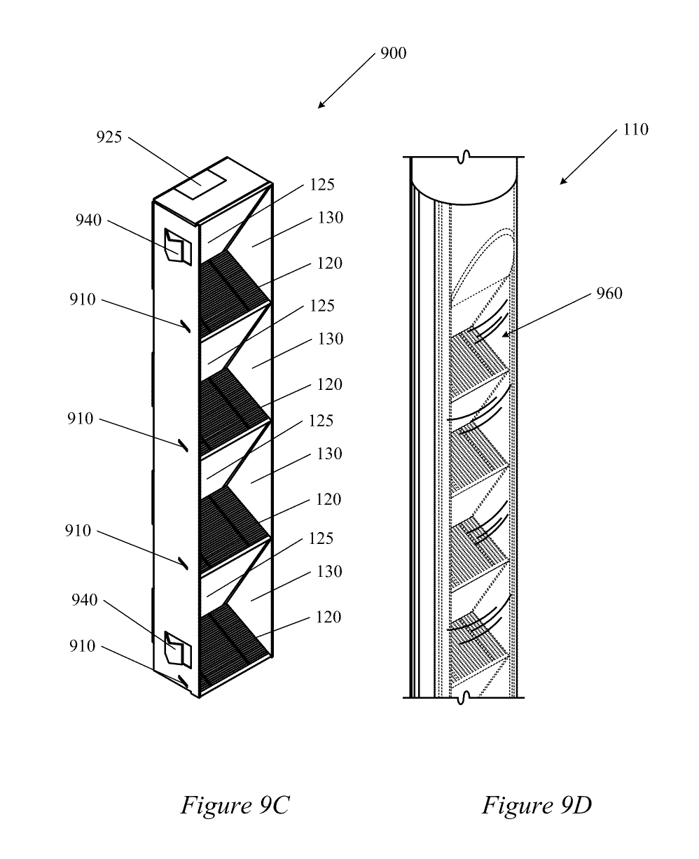

In some embodiments, channel (or aperture) 115 is provided along at least a portion of the length of solar pole 110 and more specifically along the solar section 150 of the solar pole 110. A plurality of solar cells 120 and a plurality of reflective surfaces (including, but not limited to, back reflective surface 125 and/or side reflective surfaces 130) can be disposed within channel 115. Solar cells 120 and back reflective surface 125 and/or side reflective surfaces 130 can be disposed within channel 115 as part of a solar module (e.g., solar module 355 shown in FIGS. 3 and 4 discussed in more detail below) or as part of a solar assembly (e.g., solar assembly 900 shown in FIG. 9A and FIG. 9B).

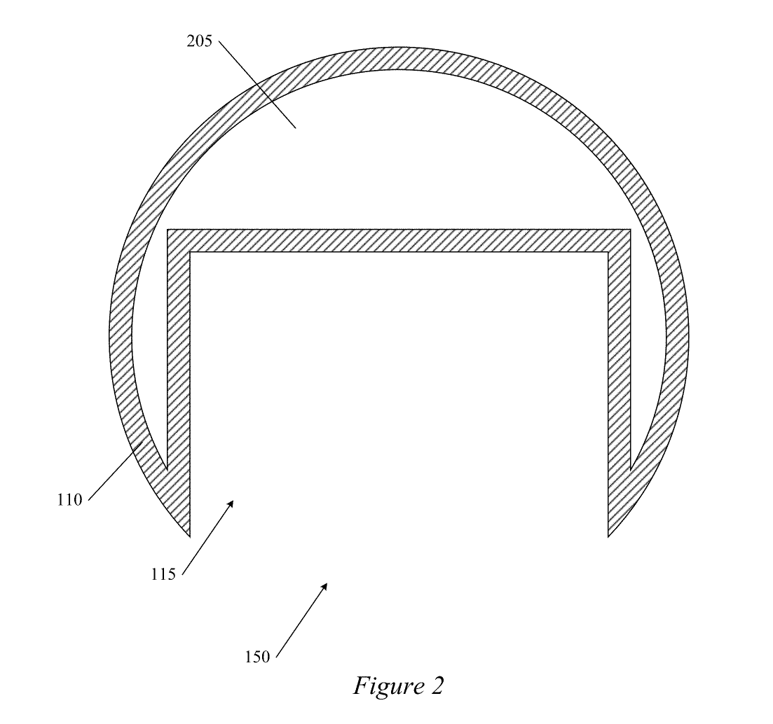

FIG. 2 illustrates one possible cross-sectional shape of solar section 150. In some embodiments, solar section 150 is substantially rounded and includes channel 115 into which solar cells 120 and/or back reflective surfaces 125 are disposed. Solar section 150 can have a substantially C-shape cross section along all or part of the pole's length, wherein channel 115 forms inner portion of the “C” in channel 115. However, the cross section of solar section 150 and/or channel 115 may have any shape; for example, U-shaped, rectangular, polygonal, or oval. Solar section 150 can be at least partially hollow so as to create a passageway 205 to facilitate convective cooling of solar cells 120 and/or to provide a chamber within which wiring may be run. Moreover, one or more vents may be provided along the length of solar section 150 to promote passive convective air current cooling of solar cells 120.

FIG. 3 shows solar module structure 300 according to some embodiments of the invention, and FIG. 4 shows a number of solar module structures 300 embedded within solar section 150 of solar pole 110. Solar module structure 300 can include a base surface 310 (onto which a solar cell 120 can be seated), a back wall 315, and two side walls 320. Reflective surfaces can be mounted onto or manufactured as part of back wall 315 and side walls 320, as discussed below. Base surface 310 can be formed of a material having suitable thermal properties to absorb heat, or transfer heat generated by a solar cell away from a solar cell (e.g., solar cell 120). Base surface 310 may or may not be highly specular or have high reflectivity. Back wall 315 and side walls 320 can be formed from a material having suitable thermal properties to absorb or transfer heat generated by solar cells 120; for example, aluminum. As another example, back wall 315 and side walls 320 can be made of non-thermally conductive material such as plastics or metalized plastics. In some embodiments, these surfaces can be highly specular and highly reflective even if such rendering reduces their heat capacity and/or thermal conductivity. Moreover, the base, back, and side walls may be integrally-formed or may be formed separately and assembled to form solar module structure 300.

As shown in FIG. 4, solar cell 120 can be positioned on base surface 310 of a solar module structure 300. Solar cell 120 can comprise any suitable solar cell 120 known to one skilled in the art. Non-limiting examples include thin-film, monocrystalline silicon and polycrystalline silicon solar cells. In some embodiments of the invention, each solar cell 120 can be individually packaged, wherein the packaging comprises a structural backing providing structural strength, thermal conductivity, and/or electrical insulation and having a similar coefficient of thermal expansion as the solar cell 120. Additionally, each solar cell 120 can have a transparent coating providing weather resistance and electrical insulation. In some embodiments, the solar cells 120 are standard sized solar cells 120, so that the overall cost and complexity of the solar pole or solar module is reduced. In some embodiments, the solar cells have standard dimensions based on the size of the ingot the solar cell material was cast into, and the remaining parameters of the solar pole or solar module are chosen to allow incorporation of the packaged solar cells without cutting or otherwise altering the standard dimensions of the solar cells.

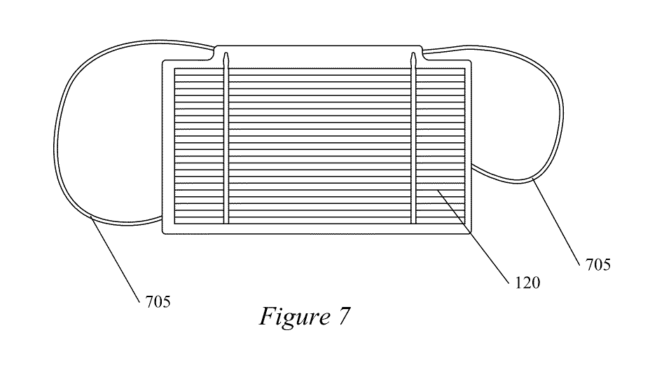

FIG. 7 is a top view of a packaged solar cell that can be used in the various embodiments of the invention. Solar cell 120 can include any number of wires 705 that can be used to conduct electricity generated at solar cell 120. In some embodiments, wires 705 can conduct electricity to a battery, a lighting circuit, and/or a power grid. Any type of device that can convert solar radiation to electricity can be used in the various embodiments.

In some embodiments, back wall 315 and/or the side walls 320 of solar module structure 300 can include reflective surfaces to form back reflective surface 125 and side reflective surfaces 130. In one embodiment, back reflective surface 125 and side reflective surfaces 130 are formed by polishing back wall 315 and side walls 320 of solar module structure 300 to render them highly reflective and/or specular. In other embodiments, back wall 315 and side walls 320 of solar module structure 300 are treated with a reflective material such as a reflective coating or formed, pre-finished reflector sheet. A non-limiting example of such a reflective material is MIRO-SUN® (Alanod-Solar GmbH & Co.). In some embodiments, some or all of the reflective surfaces can be planar.

A solar module 355 can be constructed from solar module structure 300 by coupling solar cell 120 with base surface 310, as shown in FIG. 4, and by coupling reflectors with or polishing back wall 315 and/or side wall 320 to form the back reflective surface 125 and side reflective surfaces 130 of the solar module 355. Thus, while this disclosure may discuss aspects of solar modules 355, these details can apply to solar module structures 300 and vice-versa since solar modules 355 are essentially solar module structures 300 fitted with a solar cell 120 and rendered reflective.

Multiple solar modules 355 can be arranged within the length of channel 115, as shown in FIG. 4. In some embodiments, multiple solar modules 355 can form an alternating stair-step or saw-tooth pattern. Solar modules 355 may be retained in channel 115 by any appropriate means known to one of ordinary skill in the art. For example, solar modules 355 may be bonded to a structural portion of solar section 150 within the channel 115 or retained using screws or other suitable mechanical fasteners. Solar modules 355 can, but do not have to, include tabs 365 that can be used to couple or position a solar module 355 within channel 115. Tabs 365 can extend outwardly and can engage with a slot (not shown) formed with the wall of channel 115 to secure the solar module 355 within channel 115.

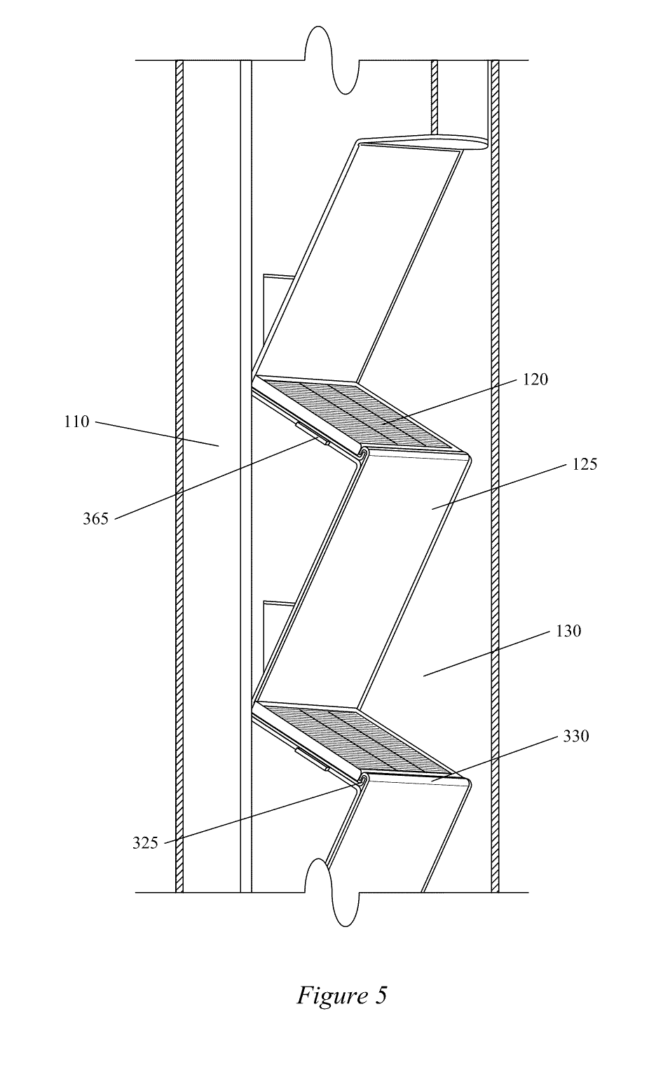

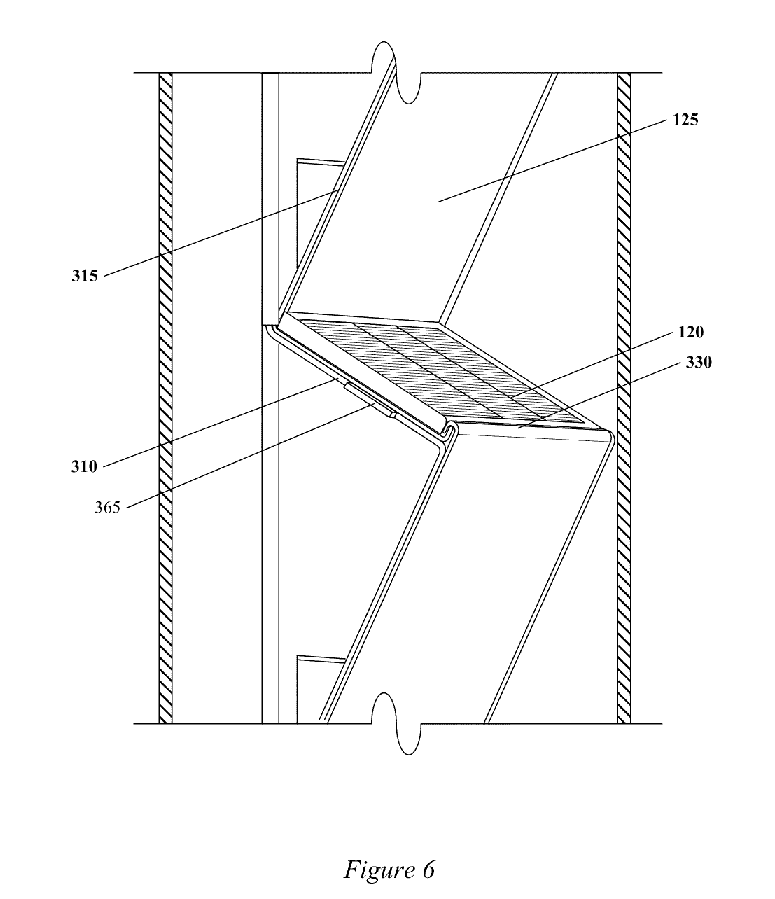

In some embodiments, multiple solar module structures 300 are not integrally-formed. Instead, solar modules 355 can be interlocked. By way of example, each solar module 355 may be provided with hook 325 (see FIG. 5) that extends from back wall 315 and a ridge 330 that extends along base surface 310 of solar module structure 300. Hook 325 of a first solar module engages ridge 330 of a second, adjacent solar module structure 300, and hook 325 of the second solar module engages ridge 330 of a third, adjacent solar module, and so on. A series of interlocked solar modules 355 are formed. Also, as shown in FIG. 3, in some embodiments, a solar module structure 300 can have slot 335 for passing wiring components (such as electrical leads) from solar cell 120 for connection (in series or parallel) to solar cells 120 of other solar modules 355.

While solar modules 355 have been described as discrete modules that are assembled together, solar modules 355 may be integrally-formed and solar cell 120 and/or reflector assembly can then be inserted into channel 115 in a modular fashion with solar modules 355. Moreover, while the solar poles described herein can include a single channel 115 and row of solar modules 355, any number of apertures (or channels) at any number of locations may be provided on solar pole 110. Moreover, solar modules 355 may be positioned adjacent other solar modules along both the length and the width of the pole such that solar modules 355 can extend side-by-side along the length of channel 115. Individual solar modules 355 may also be provided at discrete locations on solar pole 110.

Back reflective surface 125 and side reflective surfaces 130 of each solar module 355 can serve to reflect and focus light onto solar cell 120, thereby increasing the amount of light collected by an individual solar cell. In some embodiments, solar pole 110 can be oriented so that solar modules 355 face in the compass direction that maximizes sunlight incident on the solar modules—south in the northern hemisphere, for example. In some embodiments, each solar cell is exposed directly to the sun. In addition, the sun's rays striking the back reflective surface 125 and/or the side reflective surfaces 130 are at least partially reflected and directed onto solar cell 120. This is equivalent to producing additional images of the sun that are directed to solar cells 120 throughout the day to increase the total amount of energy absorbed by solar cells 120.

Solar cells 120, in turn, can be electrically tied to an electric power grid (“the grid”) (e.g., a nationwide power grid). Solar cells 120 can be tied to the power grid by any means known to one of ordinary skill in the art. For example, the energy generated by solar cells 120 can be passed through a power inverter that converts direct current (DC) power to alternating current (AC) power. Such an inverter could be located within or near solar pole 110. In daylight when a light fixture is not typically in operation (i.e., not drawing power from the grid), solar cells 120 can provide electricity to the power grid. For example, solar cells 120 could replenish power to the grid with some of the power that the lighting fixture drew from the grid the previous night. This timing can be especially advantageous because energy demand on the grid is usually highest during the day. In contrast, energy demand on the grid is lowest at night when lighting fixtures draw energy from the grid. The use of solar poles in this way obviates the need for batteries which are required in autonomous solar-powered lighting fixtures (which reduces both cost and weight), reduces maintenance requirements, and comports with more diverse and aesthetically pleasing designs. Moreover, the use of such poles largely eliminates concerns related to weather patterns and the ability to consistently achieve recommended light levels for a particular application.

In some embodiments, energy collected by solar cells 120 can be used to directly power a lighting fixture (e.g., the light source(s) in luminaire head 105) or charge a battery. Rather than replenishing the grid, energy collected by the solar cells 120 during the day can be stored locally, in batteries for instance, and then used to power the lighting fixture at night.

In some embodiments, solar pole 110 can be coupled with daytime lighting devices such as flashing traffic warning lights, flashing pedestrian crosswalk lights, stop lights, etc. In such embodiments, power generated from the solar cells 120 can directly power the lights during the day, and/or stored power or power from the grid can be used to power the lights during the night.

The angular orientation of back reflective surface 125 and side reflective surfaces 130 and solar cells 120 can be selected to maximize the amount of sunlight reflected onto solar cells 120. Base surface 310 of the solar module structure 300 can be tilted at any angle. For example, base surface 310 can be titled 20° to 30° relative to a horizontal axis. As another example, base surface 310 can be tilted 15° to 35° relative to a horizontal axis. And in yet another example, base surface 310 can be tilted 10° to 40° relative to a horizontal axis. In some embodiments, back wall 315 and side walls 320 of solar module structure 300 (and consequently the back reflective surface 125 and/or side reflective surface 130 of solar module 355) are oriented at an between about 0° and about 90° relative to solar cell 120 positioned on the base surface 310 of the solar module structure 300. For example, the angle β can be approximately 90°. The larger the angle β between the back reflective surface 125 and solar cell 120 is (i.e., the more open the solar module structure 300), the more light solar cell 120 can gather but the fewer the number of solar cells 120 that can be placed within an aperture of a given length. Similarly, decreasing the angle β allows placement of more solar cells 120 in a given length but decreases the amount of light incident upon each solar cell 120. Thus, the design of each solar module structure 300 may be tailored depending on particular applications as well as design constraints. Moreover, the geometries of a plurality of solar modules 355 (whether formed integrally or not) positioned within a solar pole 110 need not all be the same.

In addition to the geometry of solar modules 355 themselves, the orientation of solar modules 355 within channel 115 can also impact the efficacy of solar cells 120. In some embodiments, solar modules 355 are positioned in solar pole 110 so that they are tilted downwardly or upwardly between about 0° and about 40°, and in some embodiments about 30°, relative to a horizontal axis.

Solar pole 110 can be designed to efficiently and effectively dissipate the heat generated by the solar cells 120 to control the temperature of the cells and thereby reduce the detrimental impact excessive heat can have on the cells. Some of the heat generated by the solar cells 120 can be conducted to and dissipated by solar pole 110. Moreover, channel 205, formed along the length of solar pole 110, as well as any optional vents provided in solar pole 110, can convectively cool the system, carrying heat away from the solar cells 120.

Embodiments of solar modules 355 and the solar poles 110 are by no means limited to use in lighting fixtures. In some embodiments, solar modules as described above are disposed within an aperture of a pole further associated with a local energy storage device, such as a battery, that can be used to store energy generated by the solar modules during the day and later provide said stored energy to power a lighting fixture associated with the solar pole without any reliance on the power grid. In some embodiments, a lighting fixture associated with a solar pole of the present invention can be an autonomous outdoor lighting fixture.

FIG. 8 shows an example of a connecting mechanism for coupling solar section 150 with bottom section 160. Bottom section 160 includes tenon 810 with tenon cap 805. Tenon cap 805 is an end cap on the top of tenon 810. Tenon 810 is designed to slide within mortise 825 of solar section 150. Mortise 825 can include a channel or be part of a channel that extends through the entire length of solar section 150 (e.g., channel 115) or mortise 825 can extend only partially through solar section 150. Solar section 150 and bottom section 160 each have the same general shape. As shown, solar section 150 is generally C-shaped but other shapes can be used such as U-shaped. The poles can be constructed by using any extrusion methodology, by pressing them into shape, and/or by forming them into shape. The poles can have any number of internal ridges, external ridges, internal webbing, external webbing, screw slots, connectors, joints, internal formations, and/or external formations. Each solar section 150 may include mortise 825 on the opposite end of the pole to couple with a tenon of top section 170.

Tenon 810 may provide structural support to solar section 150. When coupled, tenon 810 can increase the structural strength of the joint made with solar section 150. Tenon 810 may also extend within solar section 150 and can impart structural strength to solar section 150.

Tenon 810 may include tenon cap 805. Tenon cap 805 may include cutout 815. Cutout 815 can be coupled with passageway 205 for convective cooling. Cutout 815 may also provide a channel for the electrical wires to traverse through the various portions of the poles. In some embodiments, electrical connectors can be included with tenon 810 and/or mortise 825. These electrical connections can also be used to couple the poles to a luminaire and/or the nationwide electrical grid.

In some embodiments of the invention, solar pole 110 can be constructed from solar pole modules each having a fixed length. For example, an eight foot solar pole can be constructed from four solar pole modules with two feet lengths. These solar pole modules can contain a fixed number of solar modules and have connecting mechanisms to allow them to easily and securely connect together, and can provide electrical conductivity between solar cells. By using multiple solar pole modules with a discrete length, a solar pole of longer lengths can be constructed. Thus, a solar pole can include one or more solar pole modules each having one solar module 355 or an assembly of solar modules 355.

Some embodiments of solar modules 355 are disclosed as independent modules that can be positioned and retained in a pole and may optionally be interlocked with adjacent modules. However, the solar modules 355 need not be free-standing of other modules. Rather, the solar modules 355 may be provided integral with other modules.

By way only of example, FIG. 9A shows a solar module housing 900 having four compartments 915, each configured to house a solar module (e.g., solar module 355). While the illustrated solar module housing 900 includes four compartments 915, any number of compartments 915 may be provided in the housing 900. Solar module housing 900 can have a fixed length (e.g., two feet) and be configured to house a fixed number of solar modules. Solar poles can then be populated with one or more solar module housings 900 depending on the length of the solar pole and/or on the number of solar cells required for the application. By using solar module housings 900, solar poles can be manufactured to have a channel 115 length that can accommodate multiple solar module housings 900. In some embodiments, the length of the solar module housing 900 is an even multiple of the length of the channel 115. In this way solar poles can be constructed of various lengths using multiple solar module housings 900 of a fixed length.

In some embodiments, solar module housing 900 may be constructed from non-corrosive or non-electrically conductive material. In some embodiments, all or portions of solar module housing 900 may be constructed from thermally conductive material. For example, solar module housing 900 may be constructed from galvanized steel, aluminum, resin, plastic, etc. or a combination thereof.

Ledges 905 may be used to divide the solar module housing 900 into compartments 915. In some embodiments, ledges 905 include tabs 906 that extend from the sides of each ledge 905. Slots 910 can be provided in the side walls 930 of the solar module housing 900. Tabs 906 of a ledge 905 can engage slot 910 to support ledge 905 in place within the solar module housing 900. One of skill in the art will readily understand, however, that compartments 915 may be formed in the solar module housing 900 in different ways. The slots 910 may be positioned to ensure that the ledge 905 is angled properly upon engagement of the ledge 905 with the slot 910 via tabs 906. FIG. 9B shows a side view of solar module housing 900 in which slot 910 is oriented at an angle θ and thus, by extension, so too is the ledge 905 that engages the slot. In some embodiments, slot 910 can be angled for use within a specific geographic latitude or the angle can depend on the size of solar module housing 900. In some embodiments, multiple tabs can be cut into solar module housing 900 at different angles. The manufacturer or user can then adapt the angle of the solar array depending on latitude and/or the diameter of the solar pole.

In some embodiments, a solar module 355 is inserted into each compartment 915 within the solar module housing 900. The orientation of the solar module 355 within the compartment 915 will be dictated by the orientation of ledge 905. While entire solar modules 355 may be inserted and retained within the solar module housing 900, it is also possible to convert a compartment 915 of the solar module housing 900 essentially into a solar module. This can be done by positioning a solar cell 120 on the ledge 905 of the compartment 915 and rendering reflective the inner surfaces of the solar module housing 900 within the compartment 915.

Friction tabs 940 can be used to secure solar module housing 900 within a pole. For example, friction tabs 940 can friction fit, pressure fit, or bear against the interior channel wall of a pole. Slot 925 can be used to run electrical wires through solar module housing 900, for example, using an electrical harness.

FIG. 9C shows solar module housing 900 with solar modules 355 positioned therein. Solar cells 120, back reflective surfaces 125, and side reflective surface 130 are shown. FIG. 9D shows solar module housing 900 disposed within solar section 150 of solar pole 110 and with protective lens 960. In some configurations, protective lens 960 can provide a seal with solar pole 110 and can protect against water penetration. In some embodiments, protective lens 960 can provide UV filtration or other optical benefits. In some embodiments, protective lens 960 can be constructed from an impact resistant material, for example, a polymeric material. In some embodiments, protective lens 960 can protect solar cells from damage from vandalism and the like. In some embodiments, protective lens 960 can be constructed or treated to obscure certain viewing angles for aesthetic purposes or further focus solar energy at desired angles.

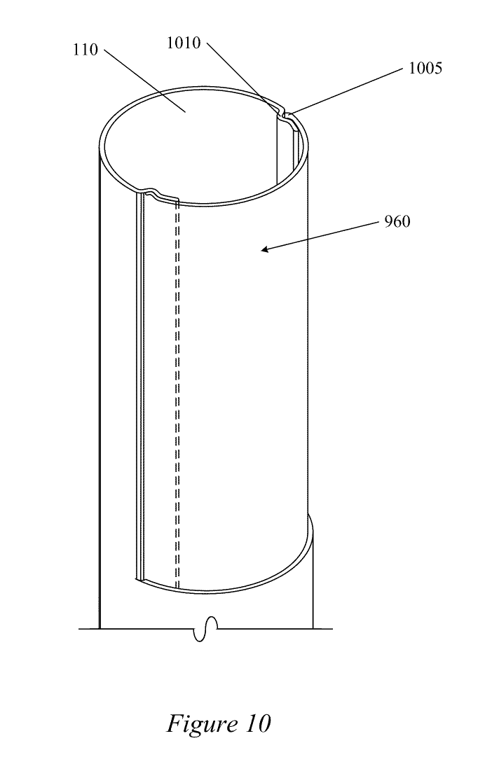

FIG. 10 shows solar pole 110 that includes protective lens 960. In some embodiments, protective lens 960 can have an outside diameter that substantially matches the outside diameter of solar pole 110. In some embodiments, protective lens 960 can have a ridge portion 1005 near or at the edge(s) of the lens that match with indentations 1010 on solar pole 110. Protective lens 960 can snap fit onto solar pole 110 via engagement between indentation 1010 and ridge portion 1005. In some embodiments, gaskets, grease, and/or seals can also be used to ensure adequate sealing.

Various embodiments of the invention have been described. These embodiments are examples describing various principles of the present invention. Numerous modifications and adaptations thereof will be readily apparent to those skilled in the art without departing from the spirit and scope of the invention. For example, the concepts described herein need not be limited to solar pole applications. Rather, solar modules described herein that incorporate planar reflectors may be incorporated into a variety of substrates, including, but not limited to, a roof or exterior wall of a building, a fence, a retaining wall, a planter, an exterior surface of an automobile, aircraft, or boat.

Different arrangements of the components depicted in the drawings or described above, as well as components and steps not shown or described are possible. Similarly, some features and subcombinations are useful and may be employed without reference to other features and subcombinations. Embodiments of the invention have been described for illustrative and not restrictive purposes, and alternative embodiments will become apparent to readers of this patent. Accordingly, the present invention is not limited to the embodiments described above or depicted in the drawings, and various embodiments and modifications can be made without departing from the scope of the claims below.

What is claimed is:

1. A solar pole comprising:
an elongated member having a length; and
a plurality of solar modules positioned at least partially within the elongated member along the length of the elongated member, wherein each solar module comprises a solar cell and at least one reflective surface.

2. The solar pole according to claim 1, wherein at least some of the plurality of solar modules are positioned one above the other along the length of the elongated member.

3. The solar pole according to claim 1, wherein at least some of the plurality of solar modules are positioned side-by-side along the length of the elongated member.

4. The solar pole according to claim 1, wherein the plurality of solar modules comprises a first solar module and a second solar module interconnected with the first solar module.

5. The solar pole according to claim 4, wherein the first solar module comprises a ridge and the second solar module comprises a hook that engages the ridge to interconnect the first and second solar modules.

6. The solar pole according to claim 1, wherein the solar cells generate electricity, wherein at least some of the plurality of solar modules are electrically connected with an electric power grid, and wherein at least some of the electricity generated by the solar cells of the solar modules is supplied to the electric power grid.

7. The solar pole according to claim 1, wherein the solar cells generate electricity, wherein at least some of the plurality of solar modules are electrically connected with a battery and wherein at least some of the solar energy generated by the solar cells of the solar modules is supplied to the battery.

8. The solar pole according to claim 1, wherein the elongated member comprises a channel and at least some of the plurality of solar modules are positioned at least partially within the channel.

9. The solar pole according to claim 1, wherein the at least one reflective surface comprises a planar reflective surface.

10. The solar pole according to claim 1, wherein the at least one reflective surface is oriented in the solar module to direct light onto the solar cell.

11. The solar pole according to claim 1, wherein the at least one reflective surface is oriented above or to the side of the solar cell.

12. The solar pole according to claim 1, wherein the at least one reflective surface comprises a planar reflective surface and the solar cell comprises a planar solar cell surface disposed at an angle relative to the planar reflective surface.

13. The solar pole according to claim 1, wherein an angle between the planar solar cell surface and at least one reflective surface is about 90°.

14. The solar pole according to claim 1, further comprising a light source.

15. The solar pole according to claim 1, wherein at least some of the plurality of solar modules are provided within a housing having a housing length.

16. The solar pole according to claim 15, wherein the elongated member comprises a channel having a channel length and wherein the housing is positioned within the channel.

17. The solar pole according to claim 16, wherein the housing length is an even multiple of the channel length.

18. The solar pole according to claim 1, wherein at least some of the plurality of solar modules are provided within a first housing and a second housing, wherein the first housing and the second housing each comprises a length and wherein the length of the first housing is the same as the length of the second housing.

19. A solar pole comprising:
an elongated pole;
a light fixture mechanically coupled with the pole and electrically coupled with an electric power grid; and
a plurality of solar modules positioned within the elongated pole, each solar module comprising at least one reflective surface and a solar cell oriented substantially perpendicular relative to each other, wherein the plurality of solar modules are electrically coupled to the electric power grid.

20. A method for harnessing energy comprising:
providing a solar pole comprising an elongated member having a plurality of solar modules positioned at least partially within the elongated member, wherein each solar module comprises a solar cell and at least one reflective surface;
electrically coupling at least some of the solar cells with an electric power grid or a battery;
generating electricity with the solar cells; and
supplying the electricity to the electric power grid or the battery.

21. The method according to claim 20, wherein the solar pole comprises an electric fixture and the method further comprises:
electrically coupling the electric fixture with the electric power grid or the battery; and
powering the electric fixture with electricity from the electric power grid or the battery.
